(19) United States
(12) Patent Application Publication
(10) Pub. No.: US 2018/0181504 A1
(43) Pub. Date: Jun. 28, 2018

(54) APPARATUSES AND METHODS FOR TRAINING ONE OR MORE SIGNAL TIMING RELATIONS OF A MEMORY INTERFACE

(71) Applicant: Intel Corporation, Santa Clara, CA (US)

(72) Inventors: Tonia Morris, Irmo, SC (US); John Van Lovelace, Irmo, SC (US); Christopher Mozak, Beaverton, OR (US); Bill Nale, Livemore, CA (US)

(21) Appl. No.: 15/389,462

(22) Filed: Dec. 23, 2016

(51) Int. Cl. G06F 13/16; G06F 3/06; G11C 11/4076; G11C 11/4093

(52) U.S. Cl. CPC G06F 13/1689; G06F 3/0614; G06F 3/0634; G06F 13/1673; G06F 3/0673; G11C 11/4076; G11C 11/4093; G06F 3/0656

(57) ABSTRACT

The present disclosure relates to an apparatus for training one or more signal timing relations of a control interface between a registering clock driver and one or more data buffers of a memory module comprising a plurality of memory chips, the control interface comprising a clock signal and at least one control signal. The apparatus includes control circuitry which is configured to adjust a relative timing between the at least one control signal and the clock signal based on samples of the at least one control signal sampled based on the clock signal

### FIELD

The present disclosure generally relates to computer memory systems and, more particularly, to memory interface training.

### BACKGROUND

Memory systems typically comprise a plurality of volatile memory integrated circuits, for example. Dynamic Random Access Memory (DRAM) integrated circuits, referred to herein as DRAM devices or chips, which are connected to one or more processors via one or more memory channels. Multiple DRAM devices may be arranged on a memory module, such as a Dual In-line Memory Module (DIMM). A DIMM includes a series of DRAM devices mounted on a Printed Circuit Board (PCB). Multiple DIMMs may be coupled to one memory channel. There are different types of memory modules, including so-called Load-Reduced DIMMs (LRDIMMs) which can be particularly useful when having many DIMMs per memory channel. LRDIMMs allow for buffering clock/address/control (“control”) signals and data on a memory module to reduce (capacitive) loading effects. Effectively, buffering can transfer loading effects from a memory channel having multiple memory slots (e.g., DIMM sockets) onto each DIMM. Some of these LRDIMMs have centrally located buffers similar to Registered DIMMs (RDIMMs). In addition to buffering Input/Output (I/O) data, these central memory buffers may buffer and retransmit command, address, and clock signals to DRAM devices of such DIMM. Other configurations may have a centrally located Registering Clock Driver (RCD) with distributed data (DQ) buffers to provide such data I/O loads more locally to edge connector pads and associated DRAM devices. These shorter trace lengths may increase data path speed and signal integrity while reducing latency on a memory channel bus.

LRDIMMs include an interface between the RCD component and the data buffers. Conventionally, this interface was designed with matched routing among clock signals, control signals, and command signals. As (clock) frequencies continuously increase, such precise matching might not result in this interface between the RCD component and the data buffers having sufficient temporal margins for reliable operation.

Thus, there is a need for concepts allowing reliable operation of the interface between the RCD component and the data buffers.

### BRIEF DESCRIPTION OF THE DRAWINGS

Some examples of apparatuses and/or methods will be described in the following by way of example only, and with reference to the accompanying figures, in which

FIG. 1 shows an example of an LRDIMM;

FIG. 2 shows an example of a memory system including an LRDIMM;

FIG. 3 illustrates an example of a control interface between an RCD and data buffers on an LRDIMM;

FIG. 4 shows a schematic block diagram of an apparatus for training one or more signal timing relations of a control interface between RCD and one or more data buffers;

FIG. 5 shows a control signal pulse sampled with different relative timing with respect to a clock signal;

FIG. 6A, B show different concepts of generating predetermined control signal patterns for training;

FIG. 7 shows a command signal word with different relative timings with respect to a chip select signal;

FIG. 8 shows a flowchart of a method for training one or more signal timing relations of a control interface between RCD and one or more data buffers;

FIG. 9 a schematic block diagram of a device implementing a memory system according to the present disclosure.

### DESCRIPTION OF EMBODIMENTS

Various examples will now be described more fully with reference to the accompanying drawings in which some examples are illustrated. In the figures, the thicknesses of lines, layers and/or regions may be exaggerated for clarity.

Accordingly, while further examples are capable of various modifications and alternative forms, some particular examples thereof are shown in the figures and will subsequently be described in detail. However, this detailed description does not limit further examples to the particular forms described. Further examples may cover all modifications, equivalents, and alternatives falling within the scope of the disclosure. Like numbers refer to like or similar elements throughout the description of the figures, which may be implemented identically or in modified form when compared to one another while providing for the same or a similar functionality.

It will be understood that when an element is referred to as being “connected” or “coupled” to another element, the elements may be directly connected or coupled or via one or more intervening elements. If two elements A and B are combined using an “or”, this is to be understood to disclose all possible combinations, i.e. only A, only B as well as A and B. An alternative wording for the same combinations is “at least one of A and B”. The same applies for combinations of more than 2 Elements.

The terminology used herein for the purpose of describing particular examples is not intended to be limiting for further examples. Whenever a singular form such as “a,” “an” and “the” is used and using only a single element is neither explicitly or implicitly defined as being mandatory, further examples may also use plural elements to implement the same functionality. Likewise, when a functionality is subsequently described as being implemented using multiple elements, further examples may implement the same functionality using a single element or processing entity. It will be further understood that the terms “comprises,” “comprising,” “includes” and/or “including,” when used, specify the presence of the stated features, integers, steps, operations, processes, acts, elements and/or components, but do not preclude the presence or addition of one or more other features, integers, steps, operations, processes, acts, elements, components and/or any group thereof.

Unless otherwise defined, all terms (including technical and scientific terms) are used herein in their ordinary meaning of the art to which the examples belong.

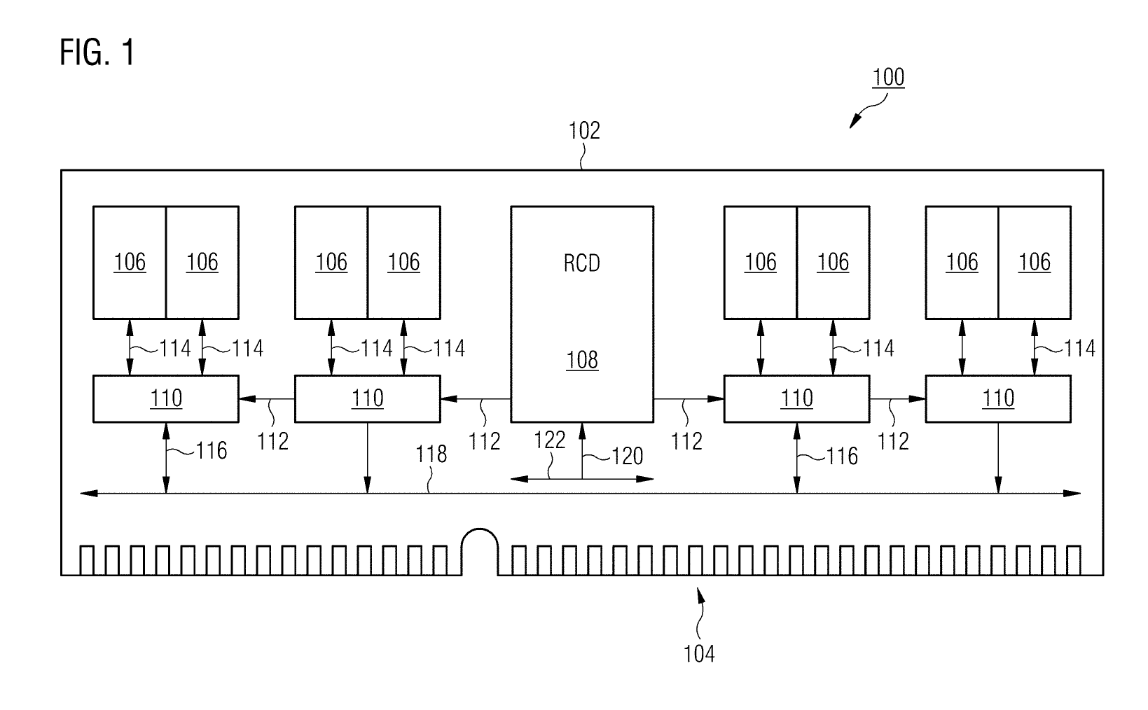

Before describing some examples according to the present disclosure in more details, a short overview of Load-Reduced DIMMs (LRDIMMs), to which concepts proposed herein may be applied, will be provided. FIG. 1 shows a schematic block diagram depicting one side of a two-sided LRDIMM 100, which can be inserted into a corresponding slot of a computer system's motherboard.

LRDIMM 100 comprises a circuit platform 102, such as a Printed Circuit Board (PCB) or other circuit platform for example, having pins 104 and having coupled thereto memory chips 106, a Registering Clock Driver chip (RCD) 108, and separate bi-directional data (DQ) buffers 110. Pins 104 could also be referred to as connectors, plugs, or solder bumps/balls (if directly soldered on the PCB instead of being inserted into a DIMM socket), for example. The memory chips 106, the RCD 108, and the data buffers 110 can all be implemented by respective individual Integrated Circuits (ICs). Note that data buffering could also be implemented centralized in the RCD chip 108, which would make it a so-called Buffering Register Clock Driver (BRCD). Though there is a one-to-two correspondence between data buffers 110 and memory chips 106 in this example, in other implementations there may be less or more memory chips 106 for each data buffer 110. In some implementations, memory chips 106 may be multi-die memory chips for increased memory density per memory chip and thus per memory module. RCD 108 is coupled to the data buffers 110 via a control bus or interface 112. Bi-directional data buses 114 are respectively coupled to memory chips 106 at one end and to data buffers 110 associated with the memory chips 106 at another end. The bi-directional data buses 114 may also be referred to as backside interface of the data buffers 110. Bi-directional data buses 116 are respectively coupled to data buffers 110 at one end and to a common data bus 118 of a memory channel at another end.

RCD 108 can terminate clock/address/control (“control”) signals 120 provided to RCD from a host memory controller (not shown) via CLK/Addr/Cont bus 122 and retime the signals to memory chips 106 and/or data buffers 110 via interface 112. Accordingly, control signals provided to pins 104 from a memory controller may be provided to RCD 108 prior to sending them to memory chips 106 and/or data buffers 110. Likewise, data to and from memory chips 106 may be strobed into or out of associated data buffers 110, subject to control of RCD 108 via control interface (data buffer control bus) 112. Accordingly, control signals and data signals provided to pins 104 from a memory controller may be provided to RCD 108 and data buffers 110 prior to sending them to memory chips 106.

The skilled person having benefit from the present disclosure will appreciate that FIG. 1 merely provides a high level overview of an LRDIMM and that actual implementation might deviate from the illustrated example. For example, while interface or bus 112 is depicted as a common bus for memory chips 106 and data buffers 110 in FIG. 1, the skilled person will appreciate that there can be separate busses between RCD 108 and memory chips 106 and RCD 108 and data buffers 110, respectively. Such and other examples will be referenced below. The term “Registering Clock Driver (RCD)” used herein refers to any device which is configured to relay clock/address/control signals provided from a host memory controller to memory chips and/or data buffers and should not be limited to specific RCDs known from RDIMMs and/or LRDIMMs. For example, an RCD can include more functionalities than only buffering or relaying clock/address/control signals. An example of such an additional functionality would be wear leveling. Wear leveling typically denotes a process that is designed to extend the life of some kinds of erasable computer storage media, such as flash memory, which is made up of microchips that store data in blocks. Each block can tolerate a finite number of program/erase cycles before becoming unreliable. Wear leveling can arrange data so that write/erase cycles are distributed evenly among all of the blocks in the device.

The skilled person having benefit from the present disclosure will further appreciate that memory chips 106 can be implemented by various types of volatile or non-volatile memory. Thus, reference to memory devices or chips can apply to different memory types. Memory devices often refers to volatile memory technologies. Volatile memory is memory whose state (and therefore the data stored on it) is indeterminate if power is interrupted to the device. Nonvolatile memory refers to memory whose state is determinate even if power is interrupted to the device. Dynamic volatile memory requires refreshing the data stored in the device to maintain state. One example of dynamic volatile memory includes DRAM (Dynamic Random Access Memory), or some variant such as synchronous DRAM (SDRAM). A memory subsystem as described herein may be compatible with a number of memory technologies, such as DDR3 (Double Data Rate version 3, original release by JEDEC (Joint Electronic Device Engineering Council) on Jun. 27, 2007, currently on release 21), DDR4 (DDR version 4, initial specification published in September 2012 by JEDEC), DDR4E (DDR version 4, extended, currently in discussion by JEDEC), LPDDR3 (Low Power DDR version 3, JESD209-3B, August 2013 by JEDEC), LPDDR4 (LOW POWER DOUBLE DATA RATE (LPDDR) version 4, JESD209-4, originally published by JEDEC in August 2014), WIO2 (Wide I/O 2 (WideIO2), JESD229-2, originally published by JEDEC in August 2014), HBM (HIGH BANDWIDTH MEMORY DRAM, JESD235, originally published by JEDEC in October 2013), DDR5 (DDR version 5, currently in discussion by JEDEC), LPDDR5 (currently in discussion by JEDEC), HBM2 (HBM version 2), currently in discussion by JEDEC), or others or combinations of memory technologies, and technologies based on derivatives or extensions of such specifications. In addition to, or alternatively to, volatile memory, in one embodiment, reference to memory devices can refer to a nonvolatile memory device whose state is determinate even if power is interrupted to the device. In one embodiment, the nonvolatile memory device is a block addressable memory device, such as NAND or NOR technologies. Thus, a memory device can also include a future generation nonvolatile devices, such as a three dimensional crosspoint (3DXP) memory device, other byte addressable nonvolatile memory devices, or memory devices that use chalcogenide phase change material (e.g., chalcogenide glass). In one embodiment, the memory device can be or include multi-threshold level NAND flash memory, NOR flash memory, single or multi-level phase change memory (PCM) or phase change memory with a switch (PCMS), a resistive memory, nanowire memory, ferroelectric transistor random access memory (FeTRAM), magnetoresistive random access memory (MRAM) memory that incorporates memristor technology, or spin transfer torque (STT)-MRAM, or a combination of any of the above, or other memory

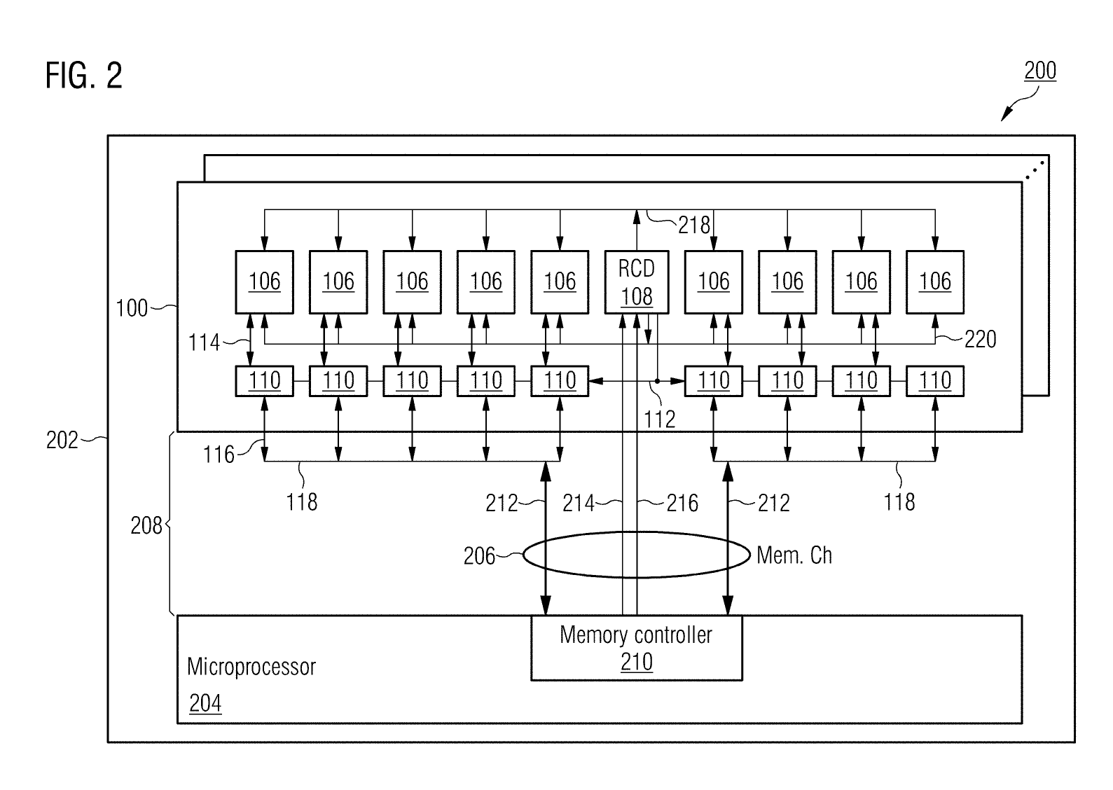

Turning now to FIG. 2, it is depicted a block diagram of an example of a processor-memory system 200 for LRDIMM 100 to which concepts proposed herein may be applied. Processor-memory system 200 may include a blade server board or motherboard 202 to which one or more LRDIMMs 100 and a data processing engine 204 (e.g., a “microprocessor 204”) can be coupled via one or more memory channels 206. One or more LRDIMMs 100 may be coupled to the same memory channel 206. LRDIMMs 100 may be able to share the same memory channel 206 by re-driving data, as well as control signals, locally on a memory module.

Bi-directional data buses 114 are respectively coupled to memory chips 106 at one end and respectively coupled to data or memory buffers 110 at another end. Bi-directional data buses 116 are respectively coupled to data or memory buffers 110 at one end and respectively coupled to a common data bus 118 at another end. This common data bus 118 may be of a memory channel 206 having traces on the motherboard 202, or a daughter card or other system board for example, which traces may generally be considered a memory bus 208. Memory bus 208 may be for a single communications channel, namely memory channel 206, even though such memory bus 208 may be used to support one, two, or more instances of LRDIMMs 100.

A memory controller 210 of microprocessor 204 may be coupled to the common data bus 118 for bidirectional communication of data signals 212. Microprocessor 204 may include at least one memory controller 210. Along those lines, if a microprocessor 204 supports multiple memory channels 206, such a microprocessor 204 may include a separate memory controller 210 for each memory channel 206. Data signals 212 may include data (“DQ”) as well as a data strobe signal (“DQS”). Accordingly, data may be strobed into or out of data buffers 110, subject to control of RCD 108. Microprocessor 204 may be a single or multi-core microprocessor.

A clock signal 214 and Command/Address (C/A) signals 216 may be provided from memory controller 210 to RCD 108. RCD 108 may buffer and relay C/A signals to each of DRAM chips 106 via a C/A bus 218, where such C/A bus can be coupled to RCD 108 and each of memory chips 106. RCD 108 may relay a clock signal to each of DRAM chips 106 via a clock bus 220 commonly coupled to RCD 108 and each of memory chips 106. RCD 108 may provide a clock signal to data buffers 110, as well as side band information associated with a decoded command via control interface 112.

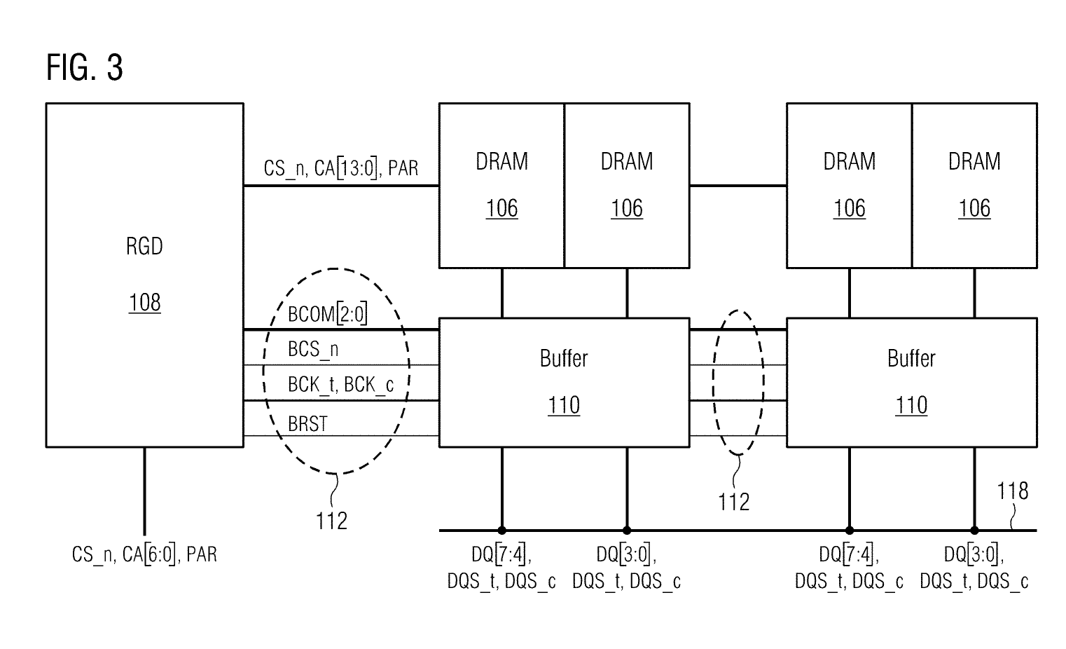

FIG. 3 provides a more detailed view of an example control interface (data buffer control bus) 112 between the RCD component 108 and the data buffers 110.

In the example of FIG. 3, the control interface or bus 112 between the RCD component 108 and the data buffers 110 comprises a plurality of different control signals. A three bit data buffer command signal BCOM [2:0] can be used to convey different commands to the data buffers 110 during normal operation of LRDIMM 100, such as read/write or buffer configuration commands, for example. The 3-bit data buffer command signal BCOM [2:0] can also be referred to as data buffer command word. A single bit buffer chip select signal BCS_n can be used to indicate the start of a data buffer command word BCOM [2:0] and/or to select one chip (or set of chips) out of several connected to the same bus, for example. A differential buffer clock signal BCK_t, BCK_c, which may be derived from a memory controller clock signal in RCD 108, for example, is used as a clock signal for the data buffers 100. The signals BCOM [2:0] and BCS_n should ideally be synchronous with clock signal BCK_t, BCK_c. A single bit asynchronous buffer reset signal BRST can be used to initialize or reset the data buffers 110.

The skilled person having benefit from the present disclosure will appreciate that the mentioned signals are mere examples and that the control interface 112 could as well comprise less, more or other signals in other example implementations.

For the JEDEC DDR4 standard, the control interface 112 between the RCD component 108 and the data buffers 110 was typically designed with matched routing among the clock signals, the control signals, and the command signals. As frequencies increase for JEDEC DDR5 standard and future JEDEC DDRx standards and beyond, such precise matching might not result in this interface having sufficient margins for reliable operation. The present disclosure therefore proposes to train timing relations between the clock signal BCK_t, BCK_c and one or more further control signals of the control interface 112. Note that the term “control signal” may be understood as to include address, control and/or command signals used to control the data buffers 110 and/or the DRAM devices 106.

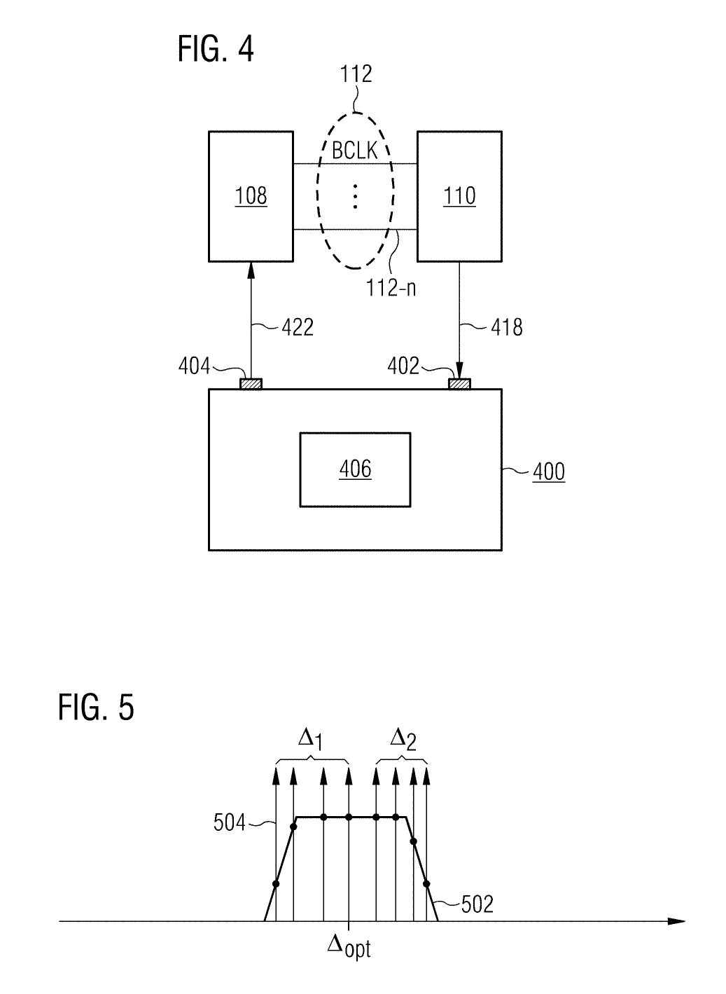

FIG. 4 illustrates a schematic block diagram of an apparatus 400 for training one or more signal timing relations of the control interface 112 between RCD 108 and one or more data buffers 110 of a memory module 100 comprising a plurality of memory chips 106. The control interface 112 comprises a clock signal BCK_t, BCK_c and at least one further control signal 112-n, such as BCS_n and/or BCOM [2:0], for example. The apparatus 400 comprises an input 402, an output 404 as well as control circuitry 406. Control circuitry 406 is configured to adjust, via output 404, a relative timing between the at least one further control signal 112-n and the clock signal BCK_t, BCK_c based on samples of the at least one further control signal sampled with the clock signal BCK_t, BCK_c and received via input 402.

Adjusting the relative timing between two signals may also be understood as synchronizing the two signals such that a center of a pulse of the clock signal BCK_t, BCK_c essentially temporally coincides with a center of a pulse of the at least one further control signal 112-n. Exact temporal coincidence of the pulse centers might not be necessary in some implementations. The at least one further control signal 112-n can be any of the BCS_n or BCOM [2:0] signals in some implementations. It can even be any other potential signal of interface 112 that should be synchronized with the clock signal BCK_t, BCK_c.

The skilled person having benefit from the present disclosure will appreciate that apparatus 400 can be implemented using one or more separate circuit components distributed over a motherboard 202. In some examples, apparatus 400 can thus optionally further comprise a data bus 418 between the one or more data buffers 110 and control circuitry 406, which may at least be partially implemented in a host memory controller. Other portions of control circuitry 406 can be implemented in RCD 108 and/or data buffers 110, for example. Data bus 418 can be used for communicating the sampled at least one further control signal 112-n from the one or more data buffers 110 to the host memory controller. Thus, at least portions of apparatus 400 may be implemented using one or more memory controllers which can be coupled to RCD 108 via one or more clock/address/control (“control”) buses 422 and to data buffers 110 via one or more data buses 418.

In some embodiments, RCD 108 can include delay circuitry for individually delaying or retiming primary clock/address/control signals received from a memory controller. The delayed clock/address/control signals can then be relayed from RCD 108 to the memory chips 106 and/or the data buffers 110 (for example via interface 112) and can thus also be referred to as secondary clock/address/control signals. Thus, in some embodiments, the control circuitry 406, such as a memory controller, for example, can be configured to adjust, in the RCD 108, a delay of the clock signal BCK_t, BCK_c and/or the at least one further control signal 112-n received from a host memory controller. This adjustment can be done by programming the RCD 108 via programming commands from a memory controller, for example. For example, a host memory controller could send Mode Register Write (MRW) commands to RCD 108 in order to modify timings.

In some examples, the control circuitry 406 can be configured to vary an adjustable relative delay between the at least one further control signal 112-n and the clock signal BCK_t, BCK_c within a range between a first relative delay and a second relative delay. In other words, a delay between signals 112-n and BCK_t, BCK_c may be changed stepwise between the first relative delay and the second relative delay. For example, there may be N (integer number larger than 1) different relative delay settings between signals 112-n and BCK_t, BCK_c. For each relative delay from the set of different delays, a predetermined control signal (sequence) having the currently set relative delay can be transmitted from RCD 108 to the one or more data buffers 110. Then, the predetermined control signal with the currently set relative delay can be sampled at the one or more data buffers 110 using the clock signal BCK_t, BCK_c. For example, a clock signal pulse can trigger the sampling of the control signal at the time instant of the clock signal pulse. Different sampling values might occur for different relative delays between the signals. For example, the relative delay can be such that a clock signal pulse coincides with an edge (rising or falling) of a control signal pulse. Such a relative timing could be a critical timing relation which should be avoided during normal operation of LRDIMM 100.

In some examples, the control circuitry 406 can be configured to set the relative timing between the at least one further control signal 112-n and the clock signal BCK_t, BCK_c based on sampled predetermined control signals corresponding to different relative delays. In other words, the relative timing can be set based on a combination of the control signal samples corresponding to different relative delays. Different types of combinations are possible, such as logical combinations, mathematical combinations, or comparisons, for example. In some examples, the control circuitry 406 can be configured to set the relative timing between the at least one further control signal 112-n and the clock signal BCK_t, BCK_c in between two relative delays corresponding to sampling time instants at falling and/or rising edges of a signal pulse of the predetermined control signal, respectively. Said differently, if the clock signal BCK_t, BCK_c coincided with a rising edge of a control signal pulse for a first relative delay and coincided with a falling edge of the control signal pulse for a second relative delay, a good choice for the relative timing between the two signals would be a relative delay in between (e.g., in the middle) the first and second relative delay. Such an example is schematically illustrated in FIG. 5.

FIG. 5 shows a control signal pulse 502 and a clock signal pulse 504 with different relative delays with respect to each other. For a first relative delay Δ₁ the clock signal pulse 504 coincides with a rising edge of control signal pulse 502. For a second relative delay Δ₂ the clock signal pulse 504 coincides with a falling edge of control signal pulse 502. FIG. 5 also shows further relative delays in between Δ₁ and Δ₂ leading to more or less optimum samples of control signal pulse 502. A good choice for synchronicity between clock signal 504 and control signal 502 is a relative delay Δₒₚₜ in the middle of the first and second relative delays Δ₁ and Δ₂ (e.g., Δₒₚₜ=(Δ₁+Δ₂)/2). The skilled person having benefit from the present disclosure will appreciate that other implementations are conceivable depending on whether signals are active high or active low. For example, if the control signal 502 is used in active low option, one could aim for centering Δₒₚₜ between the first delay Δ₁ being a falling edge and the second delay Δ₂ being a rising edge of control signal pulse 502.

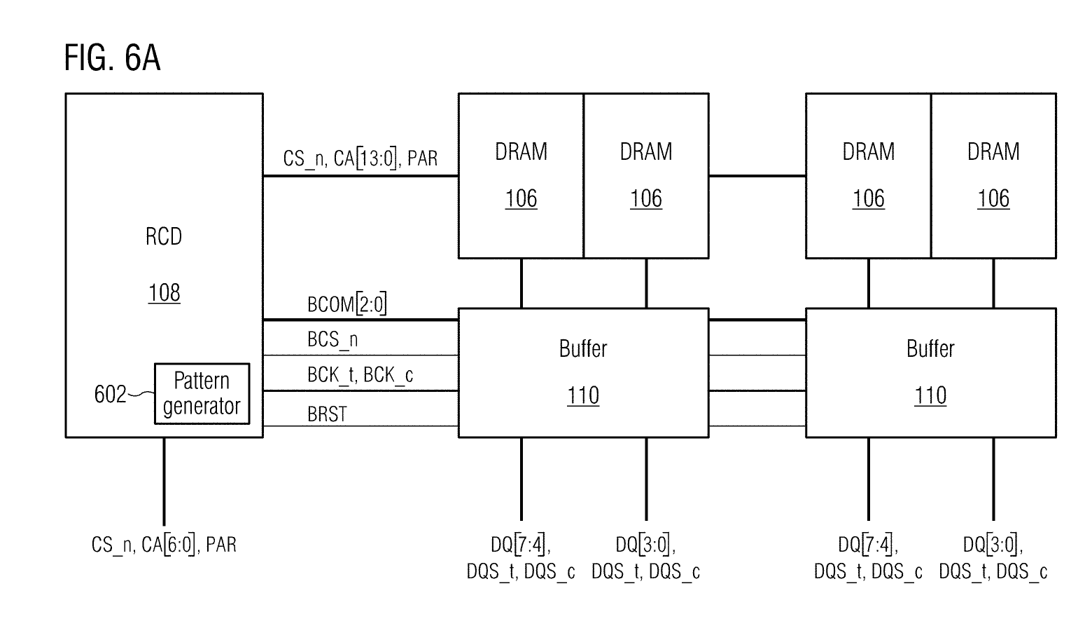

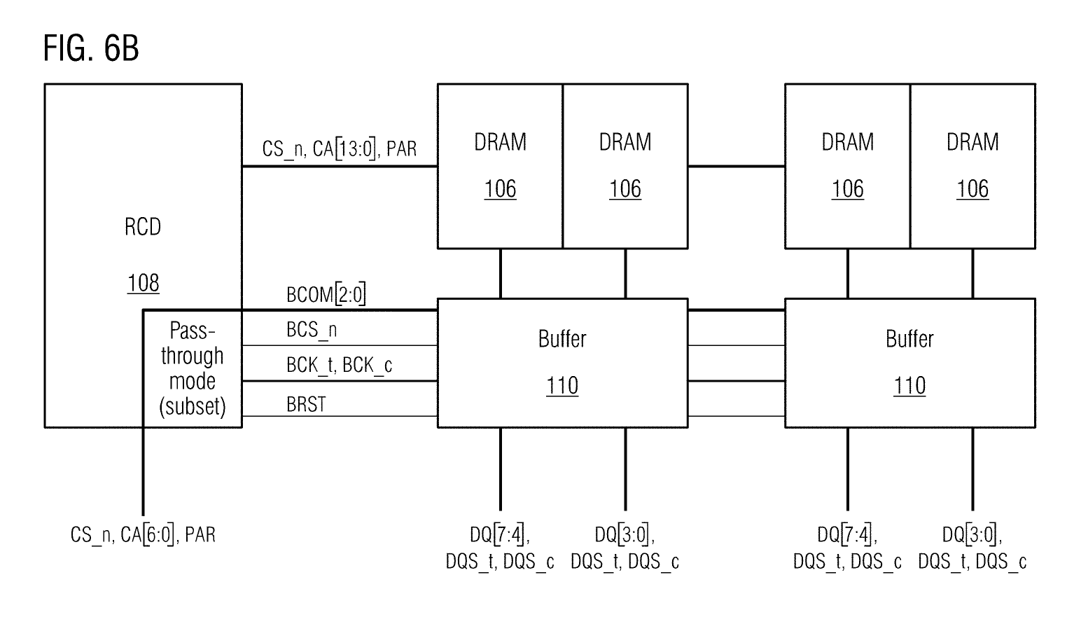

In some examples, the control circuitry 406 can comprise a pattern generator 602 in the registering clock driver 108 configured to generate the predetermined control signal. This is schematically illustrated in FIG. 6A, where RCD 108 can generate a known or predetermined control signal pattern internally. A host memory controller can send MRW commands to setup pattern details and to initiate a pattern sequence. In other examples, the control circuitry 406 can comprise a pattern generator in a host memory controller configured to generate the predetermined control signal, and an interface between the host memory controller and the RCD 108 to transmit the predetermined control signal from the host memory controller to the RCD 108, where it then can be relayed to memory buffers 110. This is schematically illustrated in FIG. 6B. Here, RCD 108 can be in a special pass-through mode to BCS_n and/or BCOM (e.g., specific host-side CA signals mapped to BCOM signals). A host memory controller can send patterns that are passed through to BCOM or BCS. Further, the host memory controller could modify timings with MRW (pass-through mode in RCD may still accept MRW's). The pattern generator in the host or RCD 108 can be configured to generate a known periodic signal pattern in some examples.

In some examples, the at least one further control signal comprises a chip select signal BCS_n and data buffer command signal BCOM [2:0]. The chip select signal BCS_n can be indicative of a packet of the data buffer command signal BCOM [2:0]. For example, it could define a start or a first bit of a BCOM packet. The control circuitry 406 can be configured to adjust a relative timing between the chip select signal BCS_n and the clock signal BCK_t, BCK_c based on samples of the chip select signal BCS_n sampled with the clock signal. Further, the control circuitry 406 can be configured to adjust a timing of the data buffer command signal BCOM [2:0] relative to the adjusted chip select signal BCS_n and/or the clock signal BCK_t, BCK_c based on evaluating a data buffer command signal packet BCOM [2:0] indicated by the timing adjusted chip select signal BCS_n.

In some examples, the control circuitry 406 can be configured to vary an adjustable relative delay between the BCS_n signal and the clock signal BCK_t, BCK_c within a range between a first relative delay and a second relative delay. In other words, a delay between signals BCS_n and BCK_t, BCK_c may be changed stepwise between the first relative delay and the second relative delay. For example, there may be N (integer number larger than 1) different relative delay settings between signals BCS_n and BCK_t, BCK_c. For each relative delay from the set of different delays, a predetermined BCS_n signal (sequence) having the currently set relative delay can be transmitted from the RCD 108 to the one or more data buffers 110. Then, the predetermined BCS_n signal with the currently set relative delay can be sampled at the one or more data buffers 110 using the clock signal BCK_t, BCK_c. Different sampling values might occur for different relative delays. For example, the relative delay can be such that a clock signal pulse coincides with an edge (rising or falling) of a BCS_n signal pulse. Such a relative timing would be a critical timing relation which should be avoided during normal operation of LRDIMM 100.

In some examples, the control circuitry 406 can be configured to set the relative timing between the BCS_n signal and the clock signal BCK_t, BCK_c based on sampled predetermined BCS_n signals corresponding to different relative delays. In other words, the relative timing can be set based on a combination of the BCS_n signal samples corresponding to different relative delays. For example, the control circuitry 406 can be configured to set the relative timing between the BCS_n signal and the clock signal BCK_t, BCK_c in between two relative delays corresponding to sampling time instants at falling or rising edges of a BCS_n signal pulse. Said differently, if the clock signal BCK_t, BCK_c coincided with a rising edge of a BCS_n signal pulse for a first relative delay and coincided with a falling edge of the BCS_n signal pulse for a second relative delay, a good choice for the relative timing between the to signals would be a relative delay in between (e.g., in the middle) the first and second relative delay as has been explained with reference to FIG. 5.

In some examples, the control circuitry can comprise a pattern generator in the registering clock driver 108 configured to generate the predetermined BCS_n signal. In other examples, the control circuitry can comprise a pattern generator in a host memory controller configured to generate the predetermined BCS_n signal, and an interface between the host memory controller and the RCD 108 to transmit the predetermined BCS_n signal from the host memory controller to the RCD 108. This has been explained with reference to FIGS. 6A and 6B. The pattern generator can be configured to generate a known periodic signal pattern in some examples.

In some embodiments, RCD 108 can include delay circuitry for delaying or retiming primary BCS_n signals received from a memory controller. The delayed BCS_n signals can then be relayed to the data buffers 110 (for example via interface 112) and can thus also be referred to as secondary BCS_n signals. Thus, in some embodiments, the control circuitry 406, such as a memory controller, for example, can be configured to adjust, in the RCD 108, a (relative) delay of the clock signal BCK_t, BCK_c and/or the BCS_n signal received from a host memory controller. This adjustment can be done by programming the RCD via programming commands from a memory controller, for example.

In some examples, apparatus 400 can comprise a data bus 418 between the one or more data buffers 110 and a host memory controller 406 for communicating the sampled BCS_n signal from the one or more data buffers 110 to the host memory controller 406.

Once the relative timing between the BCS_n signal and the clock signal BCK_t, BCK_c has been trained, the BCOM [2:0] signal can be time aligned with the synchronized BCS_n signal (and thus also with the clock signal BCK_t, BCK_c). For that purpose, the control circuitry 406 can be configured to vary an adjustable relative delay between the BCOM [2:0] signal and the BCS_n signal within a range between a first relative delay and a second relative delay. In other words, a delay between signals BCOM [2:0] and BCS_n may be changed stepwise between the first relative delay and the second relative delay. For example, there may be N (integer number larger than 1) different relative delay settings between signals BCOM [2:0] and BCS_n. For each relative delay from the set of different delays, a predetermined BCOM [2:0] signal (sequence) having the currently set relative delay can be transmitted from the RCD 108 to the one or more data buffers 110. Then, the predetermined BCOM [2:0] signal with the currently set relative delay can be sampled at the one or more data buffers 110 using the clock signal BCK_t, BCK_c and bits of the resulting data buffer command signal packet BCOM [2:0] indicated by the BCS_n signal can be evaluated, for example by a logical bit combination. In some examples, the control circuitry 406 can be configured to combine the bits of the resulting data buffer command signal packet BCOM [2:0] by an XOR operation.

In some examples, apparatus 400 can comprise a data bus 418 between the one or more data buffers 110 and a host memory controller 406 for communicating the combination of the samples of the data buffer command signal packet BCOM [2:0] from the one or more data buffers 110 to the host memory controller 406.

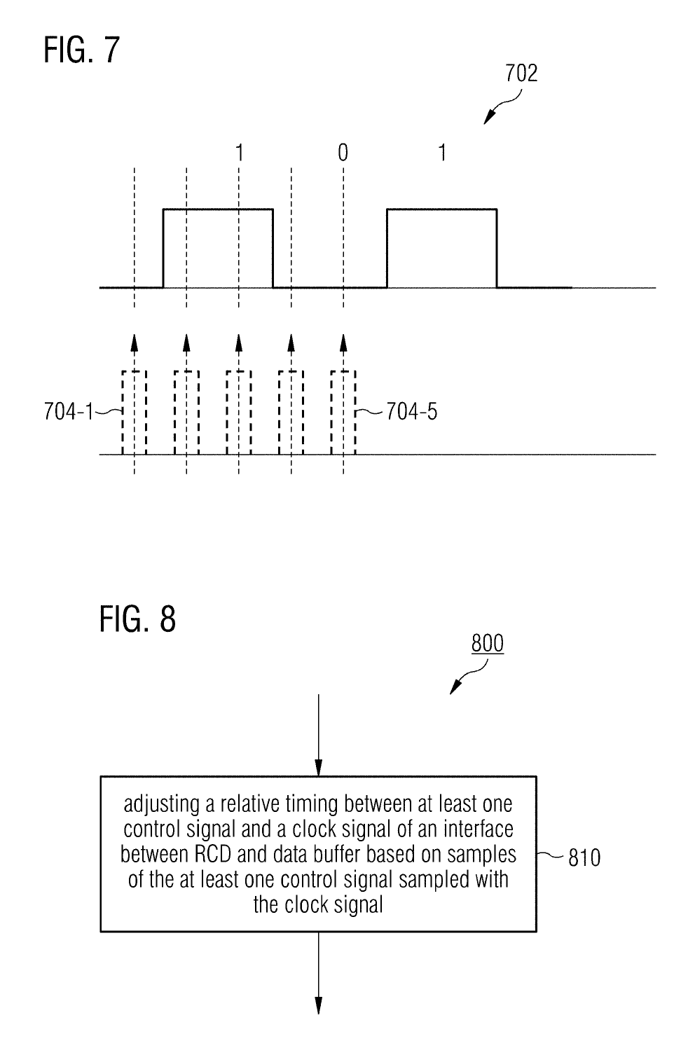

For example, the control circuitry 406 can be configured to set the relative timing between the BCS_n signal and the BCOM [2:0] signal in between two relative delays which both lead to false results of the logical combination. Said differently, if the logical combination of the bits of the data buffer command signal packet BCOM [2:0] leads to a false result (e.g., a result not corresponding to the predicted result) for a first relative delay and leads to a false result for a second relative delay while correct results are delivered for delays in between the first and second relative delay, a good choice for the relative timing between the to signals would be a relative delay in between (e.g., in the middle of) the first and second relative delay. This is illustrated in FIG. 7.

FIG. 7 shows an example of a BCOM[2:0] word 702 (e.g., “101”) with different relative delays to a BCS_n signal pulse 704. Note that a BCS_n signal pulse 704 can indicate the beginning and thus the first sample of the BCOM[2:0] word, while the BCOM signal (e.g., subsequent samples) would be sampled at clock pulse instances using the clock signal. Thus, if the BCS_n signal pulses and the BCOM[2:0] words are not synchronized properly and a BCS_n signal pulse does not point to the actual start of a BCOM word, the latter might not be interpreted correctly. For example, the relative timing between BCOM[2:0] word 702 and BCS_n signal pulse 704-1 shown in FIG. 7 would lead to wrong sampling values for the bits of BCOM[2:0] word 702. Instead of “101” the resulting samples would be “010”. Thus their logical combination (e.g., XOR) would not lead to the expected result. The same would hold for the relative timing between BCOM[2:0] word 702 and BCS_n signal pulses 704-4 or 704-5. Thus, a good training result here would be a relative timing between signals 702 and 704 essentially corresponding to the middle of the relative timings of BCS_n signal pulses 704-1 and 704-4. Note that a delay of the BCOM signal with respect to the BCS_n signal (and clock signal) may be adjusted here, since the BCS_n signal already may have been time aligned with the clock signal previously.

In some examples, the control circuitry 406 can comprise a pattern generator in the registering clock driver 108 configured to generate the predetermined BCOM [2:0] signal. In other examples, the control circuitry can comprise a pattern generator in a host memory controller configured to generate the predetermined BCOM [2:0] signal, and an interface between the host memory controller and the RCD 108 to transmit the predetermined BCOM [2:0] signal from the host memory controller to the RCD 108. This has been explained with reference to FIGS. 6A and 6B.

In some embodiments, RCD 108 can include delay circuitry for delaying or retiming primary BCOM [2:0] signals received from a memory controller. The delayed BCOM [2:0] signals are then relayed to the data buffers 110 via interface 112 and can thus also be referred to as secondary BCOM [2:0] signals. Thus, in some embodiments, the control circuitry 406, such as a memory controller, for example, can be configured to adjust, in the RCD 108, a (relative) delay of the clock signal BCK_t, BCK_c and/or the BCOM [2:0] signal received from a host memory controller. This adjustment can be done by programming the RCD via programming commands from a memory controller, for example.

In some examples, the control circuitry 406 can be configured or operable to configure different modes of operation of the RCD 108 and/or the one or more data buffers 110. Thereby the different modes could comprise at least one control signal delay training mode (e.g., prior to normal operation) and a normal or functional operation mode. For example, the control circuitry 406 can be configured to configure a first mode of operation of the one or more data buffers based on a first static value of the at least one further control signal 112-n and to configure a second mode of operation of the one or more data buffers based on a second, different static value of the at least one further control signal 112-n, which could be any of the signals BCOM [2:0], BCS_n, or BRST or a combination thereof.

In some examples, the control circuitry 406 can further optionally be configured to configure a first reference voltage V_{ref,1} of the one or more data buffers based on a first static data bus signal and to configure a second reference voltage V_{ref,2} based on a second, different static data bus signal. Thereby, the reference voltage V_{ref} of the one or more data buffers can be compared to voltage levels of the at least one further control signal 112-n in order to decide whether a logical “0” or a logical “1” was received. Further, the control circuitry 406 can further optionally be configured to configure a first On-Die termination (ODT) resistance of the one or more data buffers based on a first static data bus signal and to configure a second ODT resistance based on a second, different static data bus signal. Thereby, ODT refers to a technology where the termination resistor for impedance matching in transmission lines is located inside a semiconductor chip, e.g. the data buffer 110.

The skilled person having benefit from the present disclosure will appreciate that apparatus 400 can be used to carry out a method in accordance with the present disclosure. An example of such a method 800 for training one or more signal timing relations of a control interface 112 between a RCD 108 and one or more data buffers 110 of a memory module 100 comprising a plurality of memory chips 106 is shown in FIG. 8.

The control interface 112 comprises a clock signal and at least one further control signal 112-n. Method 800 includes adjusting or training 810 a relative timing between the at least one further control signal 112-n and the clock signal based on samples of the at least one further control signal sampled with the clock signal. Possible details of method 800 can be derived from example implementations of apparatus 400.

Before the training of the interface 112, the involved hardware components, such as RCD 108 and data buffers 110, can enter one or more specific training modes, respectively. For example, is proposed to initialize termination values and receiver V_{ref} values in the data buffers 110 prior to training the interface 112 from the RCD 108 to the buffers 110. An example process could be as follows:

1. Host memory controller 210 can program RCD 108 to drive static values to the buffers 110 on the BCOM signals.

2. Host memory controller 210 can program static values driven to the buffers on the data (DQ) interface 116, 118.

3. Host memory controller 210 can program RCD 108 to initiate a BRST pulse to the buffers 110.

4. Based on different static values on the BCOM signals, the buffer 110 can do one of the following:
a. Enter normal operating mode (e.g., reset Vref and ODT) in case of a first static value on the BCOM signals.
b. Enter BCS_n Training Mode (e.g., don't reset Vref and ODT) in case of a second static value on the BCOM signals.
c. Enter BCOM Training Mode (e.g., don't reset Vref and ODT) in case of a third static value on the BCOM signals.
d. Set the Termination for the interface (e.g., via payload from DQ settings) in case of a fourth static value on the BCOM signals.
e. Set the Vref for the interface (e.g., via payload from DQ settings) in case of a fifth static value on the BCOM signals

The following table illustrates an example for a mapping between different static values on the BCOM signals and different data buffer states:

| BCOM Static Value | Buffer State |
|---|---|
| 111 | Normal operation |
| 010 | CS Training |
| 011 | CA/BCOM Training |
| 101 | Set BCOM ODT (DQ payload) |
| 100 | Set BCOM Vref (DQ payload) |

In an example, buffer 110 can capture the encoding on the BCOM signal pins when BRST asserts. If BCOM ODT or BCOM V_{ref} are set, the payload for the setting can statically be communicated on DQ pins by a host memory controller.

After the initial ODT and V_{ref} settings are complete, and the BCS_n training mode has been enabled, the following example features in the RCD 108 and buffer 110 can support training of the BCS_n timing relative to the clock:

1. Pattern generator 602 in the RCD to drive a periodic sequence on the BCS_n signal, or the ability to pass a value from the host RCD command interface to the BCS_n signal.

2. Sampling of the BCS_n signal with primary and secondary rising edges of the clock in the buffer 110.

3. Sending the sample of the BCS_n signal on the DQ signals from buffer 110 to the host memory controller.

4. Delay settings in the RCD 108 that host memory controller can program through the host command interface, to adjust the BCS_n and clock timings.

After control Signal Training is complete, the pre-training method can be used to switch to BCOM training. The following features in the RCD 108 and buffer 110 can support training of the BCOM timing relative to the clock and BCS_n:

1. Pattern generator in the RCD 108 to drive a programmable sequence on the BCOM signals, or the ability to pass values from the host RCD command interface to the BCOM signals.

2. XOR of the BCOM signals when the BCS_n signal is asserted in the buffer 110.

3. Sending the result of the BCOM XOR operation on the DQ signals from the buffer to the host.

4. Delay settings in the RCD 108 that host memory controller can program through the host command interface, to adjust the BCOM signal timings.

Examples of the present disclosure might be particularly useful for LRDIMMs comprising a plurality of DRAM chips.

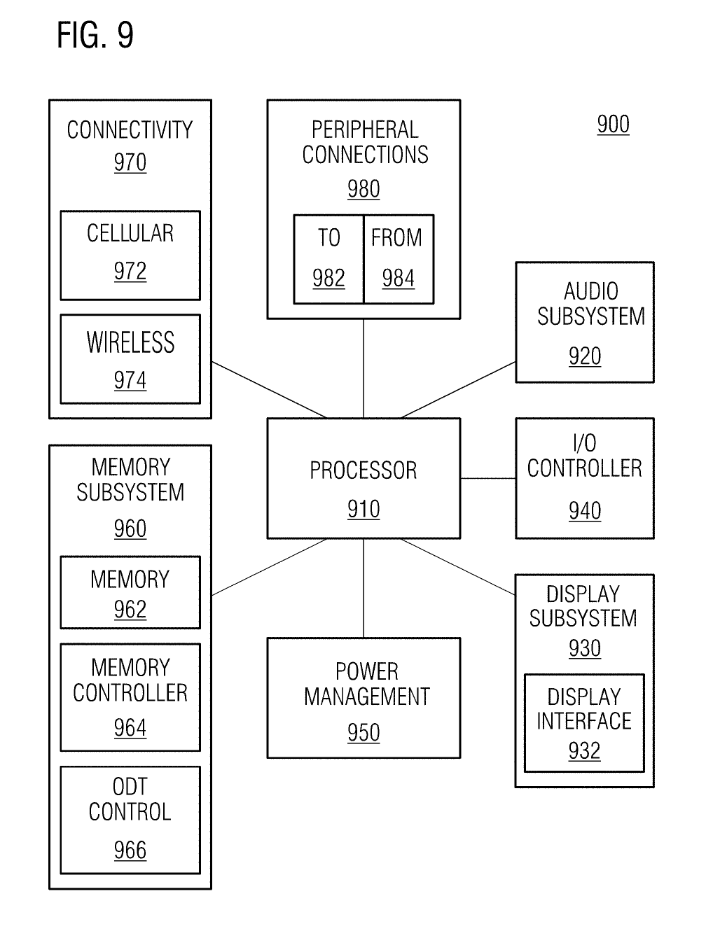

FIG. 9 is a more detailed block diagram of an example of a device in which training one or more signal timing relations of a control interface between a RCD and one or more data buffers according to example implementations can be implemented. Device 900 can represent various kinds of computing device such as a server or some other kind of computing device, such as a stationary or mobile computing device, such as a computing tablet, a mobile phone or smartphone, a wireless-enabled e-reader, wearable computing device, or other mobile device. It will be understood that certain of the components are shown generally, and not all components of such a device are shown in device 900.

Device 900 includes processor 910, which performs the primary processing operations of device 900. Processor 910 can include one or more physical devices, such as microprocessors, application processors, microcontrollers, programmable logic devices, or other processing means. The processing operations performed by processor 910 include the execution of an operating platform or operating system on which applications and/or device functions are executed. The processing operations include operations related to I/O (input/output) with a human user or with other devices, operations related to power management, and/or operations related to connecting device 900 to another device. The processing operations can also include operations related to audio I/O and/or display I/O.

In one embodiment, device 900 includes audio subsystem 920, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into device 900, or connected to device 900. In one embodiment, a user interacts with device 900 by providing audio commands that are received and processed by processor 910.

Display subsystem 930 represents hardware (e.g., display devices) and software (e.g., drivers) components that provide a visual and/or tactile display for a user to interact with the computing device. Display subsystem 930 includes display interface 932, which includes the particular screen or hardware device used to provide a display to a user. In one embodiment, display interface 932 includes logic separate from processor 910 to perform at least some processing related to the display. In one embodiment, display subsystem 930 includes a touchscreen device that provides both output and input to a user. In one embodiment, display subsystem 930 includes a high definition (HD) display that provides an output to a user. High definition can refer to a display having a pixel density of approximately 100 PPI (pixels per inch) or greater, and can include formats such as full HD (e.g., 1080p), retina displays, 4K (ultra high definition or UHD), or others.

I/O controller 940 represents hardware devices and software components related to interaction with a user. I/O controller 940 can operate to manage hardware that is part of audio subsystem 920 and/or display subsystem 930. Additionally, I/O controller 940 illustrates a connection point for additional devices that connect to device 900 through which a user might interact with the system. For example, devices that can be attached to device 900 might include microphone devices, speaker or stereo systems, video systems or other display device, keyboard or keypad devices, or other I/O devices for use with specific applications such as card readers or other devices.

As mentioned above, I/O controller 940 can interact with audio subsystem 920 and/or display subsystem 930. For example, input through a microphone or other audio device can provide input or commands for one or more applications or functions of device 900. Additionally, audio output can be provided instead of or in addition to display output. In another example, if display subsystem includes a touchscreen, the display device also acts as an input device, which can be at least partially managed by I/O controller 940. There can also be additional buttons or switches on device 900 to provide I/O functions managed by I/O controller 940.

In one embodiment, I/O controller 940 manages devices such as accelerometers, cameras, light sensors or other environmental sensors, gyroscopes, global positioning system (GPS), or other hardware that can be included in device 900. The input can be part of direct user interaction, as well as providing environmental input to the system to influence its operations (such as filtering for noise, adjusting displays for brightness detection, applying a flash for a camera, or other features). In one embodiment, device 900 includes power management 950 that manages battery power usage, charging of the battery, and features related to power saving operation.

Memory subsystem 960 includes memory device(s) 962 for storing information in device 900. Memory subsystem 960 can include nonvolatile (state does not change if power to the memory device is interrupted) and/or volatile (state is indeterminate if power to the memory device is interrupted) memory devices. Memory 960 can store application data, user data, music, photos, documents, or other data, as well as system data (whether long-term or temporary) related to the execution of the applications and functions of system 900. In one embodiment, memory subsystem 960 includes memory controller 964 (which could also be considered part of the control of system 900, and could potentially be considered part of processor 910). Memory controller 964 includes a scheduler to generate and issue commands to memory device 962. Memory subsystem 960 can implement example memory systems of the present disclosure for training one or more signal timing relations of a control interface between a RCD and one or more data buffers of a memory module. Such a memory system may be similar to FIG. 2 and comprise a memory controller 210, at least one memory module 100 comprising a plurality of memory chips 106, a RCD 108, and one or more data buffers 110 associated with the plurality of memory chips 106, an internal interface 112 between the RCD 108 and the one or more data buffers 110, the internal interface 112 comprising a clock signal and at least one control signal, an external control bus 216 between the memory controller 210 and the RCD 108, an external data bus 118 between the memory controller 210 and the one or more data buffers 110. Thereby the memory controller 210 is configured to adjust, via the external control bus 216, a relative timing of the internal interface 112 between the at least one control signal and the clock signal based on samples of the at least one control signal sampled at the one or more data buffers 110 based on the clock signal and communicated to the memory controller 210 via the external data bus 118.

Connectivity 970 includes hardware devices (e.g., wireless and/or wired connectors and communication hardware) and software components (e.g., drivers, protocol stacks) to enable device 900 to communicate with external devices. The external device could be separate devices, such as other computing devices, wireless access points or base stations, as well as peripherals such as headsets, printers, or other devices.

Connectivity 970 can include multiple different types of connectivity. To generalize, device 900 is illustrated with cellular connectivity 972 and wireless connectivity 974. Cellular connectivity 972 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), or other cellular service standards. Wireless connectivity 974 refers to wireless connectivity that is not cellular, and can include personal area networks (such as Bluetooth), local area networks (such as Wi-Fi), and/or wide area networks (such as WiMAX), or other wireless communication, such as NFC. Wireless communication refers to transfer of data through the use of modulated electromagnetic radiation through a non-solid medium. Wired communication occurs through a solid communication medium.

Peripheral connections 980 include hardware interfaces and connectors, as well as software components (e.g., drivers, protocol stacks) to make peripheral connections. It will be understood that device 900 could both be a peripheral device (“to” 982) to other computing devices, as well as have peripheral devices (“from” 984) connected to it. Device 900 commonly has a “docking” connector to connect to other computing devices for purposes such as managing (e.g., downloading and/or uploading, changing, synchronizing) content on device 900. Additionally, a docking connector can allow device 900 to connect to certain peripherals that allow device 900 to control content output, for example, to audiovisual or other systems.

In addition to a proprietary docking connector or other proprietary connection hardware, device 900 can make peripheral connections 980 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other type.

The present disclosure proposes a concept and associated hardware features and software flow to support training and/or initialization of a backside command interface/bus for LRDIMM's. The backside command interface is between the RCD component 108 and the DQ buffer 108. It may be critical to have a training flow for this interface as we get to higher frequencies supported by DDR5 and beyond. Otherwise the reliability of the interface between the RCD 108 and buffer 110, which communicates data transaction commands, could be compromised. Examples of the present disclosure allow the interface to be trained prior to any alignment of the signals, and prior to the data interface training. Previous implementations (e.g. DDR4) did not support this capability, and relied on board routing matching on the DIMM. With higher frequencies planned for DDR5, the previous approach may fail to initialize to a functional operating point.

The following examples pertain to further embodiments.

Example 1 is an apparatus for training one or more signal timing relations of a memory interface. The apparatus comprises control circuitry configured to adjust a relative timing between at least one control signal and a clock signal of a control interface between a registering clock driver and one or more data buffers of a memory module based on samples of the at least one control signal sampled based on the clock signal.

In Example 2, the apparatus of Example 1 can further comprise a data bus between the one or more data buffers and a host memory controller for communicating the sampled at least one further control signal from the one or more data buffers to the host memory controller.

In Example 3, the control circuitry of any one of the previous Examples can be configured to adjust, in the registering clock driver, a delay of the clock signal or the at least one further control signal received from a host memory controller.

In Example 4, the control circuitry of any one of the previous Examples can be configured to vary an adjustable relative delay between the at least one further control signal and the clock signal within a first relative delay and a second relative delay, for each relative delay, transmit a predetermined control signal having the relative delay from the registering clock driver to the one or more data buffers, and, for each relative delay, sample the predetermined control signal at the one or more data buffers using the clock signal.

In Example 5, the control circuitry of Example 4 can be configured to set the relative timing between the at least one further control signal and the clock signal based on sampled predetermined control signals corresponding to different relative delays.

In Example 6, the control circuitry of Example 4 or 5 can be configured to set the relative timing between the at least one further control signal and the clock signal in between two relative delays corresponding to sampling time instants at falling or rising edges of a signal pulse of the predetermined control signal.

In Example 7, the control circuitry of any one of Examples 4 to 6 can comprise a pattern generator in the registering clock driver configured to generate the predetermined control signal.

In Example 8, the control circuitry of any one of Examples 4 to 6 can comprise a pattern generator in a host memory controller configured to generate the predetermined control signal, and an interface between the host memory controller and the registering clock driver to transmit the predetermined control signal from the host memory controller to the registering clock driver.

In Example 9, the at least one further control signal of any one of the previous Examples can comprise a chip select signal and data buffer command bus, wherein the chip select signal is indicative of a packet on the data buffer command bus. The control circuitry can be configured to adjust a relative timing between the chip select signal and the clock signal based on samples of the chip select signal sampled with the clock signal, and to adjust a timing of the data buffer command bus relative to the adjusted chip select signal based on a combination of data buffer command bus signals asserted using the adjusted chip select signal.

In Example 10, the control circuitry of Example 9 can be configured to vary an adjustable relative delay between the chip select signal and the clock signal within a first relative delay and a second relative delay, for each relative delay, transmit a predetermined chip select signal using the current relative delay from the registering clock driver to the one or more data buffers, and, for each relative delay, sample the predetermined chip select signal at the one or more data buffers at rising or falling edges of the clock signal.

In Example 11, the control circuitry of Example 10 can be configured to set the relative timing between the chip select signal and the clock signal in between two relative delays corresponding to sampling time instants at falling or rising edges of a signal pulse of the predetermined chip select signal.

In Example 12, the control circuitry of Example 10 or 11 can comprise a pattern generator in the registering clock driver configured to generate a predetermined chip select signal sequence.

In Example 13, the control circuitry of any one of Examples 10 to 12 can comprise a pattern generator in a host memory controller configured to generate a predetermined chip select signal sequence, and an interface between the host memory controller and the registering clock driver to transmit the predetermined chip select signal sequence from the host memory controller to the registering clock driver.

In Example 14, the control circuitry of Example 13 can comprise adjustable delay circuitry in the registering clock driver configured to adjust the relative delay between a buffered chip select signal received from the host memory controller and the clock signal based on a command signal from the host memory controller.

In Example 15, the apparatus of any one of Examples 9 to 14 can comprise a data bus between the one or more data buffers and a host memory controller for communicating the sampled chip select signal from the one or more data buffers to the host memory controller.

In Example 16, the control circuitry of any one of Examples 9 to 14 can be configured to vary an adjustable relative delay between the data buffer command bus and the adjusted chip select signal within a first relative delay and a second relative delay, for each relative delay, transmit from the registering clock driver to the one or more data buffers, predetermined data buffer command bus signals using the current relative delay, and for each relative delay, combine the predetermined data buffer command bus signals corresponding to an associated chip select signal.

In Example 17, the control circuitry of Example 16 can be configured to configured to combine the predetermined data buffer command bus signals by an XOR operation.

In Example 18, the control circuitry of Example 16 or 17 can be configured to set the relative timing between the data buffer command bus signals and the clock signal in between two relative delays corresponding to false results of the (logical) combination of the predetermined data buffer command bus signals.

In Example 19, the control circuitry of any one of Examples 16 to 18 can comprise a pattern generator in the registering clock driver configured to generate predetermined data buffer command bus signals.

In Example 20, the control circuitry of any one of Examples 16 to 18 can comprise a pattern generator in a host memory controller configured to generate the predetermined data buffer command bus signals, and a control bus between the host memory controller and the registering clock driver to transmit the predetermined data buffer command bus signals from the host memory controller to the registering clock driver.

In Example 21, the control circuitry of any one of Examples 16 to 20 can comprise adjustable delay circuitry in the registering clock driver configured to adjust the relative delay between buffered data buffer command bus signals received from the relative host memory controller and the chip select signal based on a command signal from the host memory controller.

In Example 22, the apparatus of any one of Examples 16 to 21 can comprise a data bus between the one or more data buffers and a host memory controller for communicating the combination of data buffer command bus signals from the one or more data buffers to the host memory controller.

In Example 23, the control circuitry of any one of the previous Examples can be configured to configure different modes of operation of the registering clock driver and/or the one or more data buffers, the different modes comprising at least one control signal delay training mode and a normal operation mode.

In Example 24, the control circuitry of Example 23 can be configured to configure a first mode of operation of the one or more data buffers based on a first static value of the at least one further control signal and to configure a second mode of operation of the one or more data buffers based on a second, different static value of the at least one further control signal.

In Example 25, the control circuitry of Example 23 or 24 can be configured to configure a first reference voltage of the one or more data buffers based on a first static data bus signal and to configure a second reference voltage based on a second, different static data bus signal.

In Example 26, the memory module of any one of the previous Examples can be an LRDIMM comprising a plurality of DRAM chips.

Example 27 is a memory system comprising a memory controller, a memory module comprising a plurality of memory chips, a registering clock driver, and one or more data buffers associated with the plurality of memory chips, and an internal interface between the registering clock driver and the one or more data buffers the internal interface comprising a clock signal and at least one control signal, an external control bus between the memory controller and the registering clock driver; an external data bus between the memory controller and the one or more data buffers. The memory controller is configured to adjust, via the external control bus, a relative timing of the internal interface between the at least one control signal and the clock signal based on samples of the at least one control signal sampled at the one or more data buffers based on the clock signal and communicated to the memory controller via the external data bus.

In Example 28, the memory controller of Example 27 can be configured to set a relative timing between the control signal and the clock signal, to send a predetermined control signal with the set relative timing from the registering clock driver to the one or more data buffers, and to sample the predetermined control signal at the one or more data buffers using the clock signal.

In Example 29, the memory controller of Example 27 or 28 can be configured to select the relative timing between the at least one control signal and the clock signal based on sampled predetermined control signals corresponding to different relative timings.

In Example 30, the memory module of any one of Examples 27 to 29 can be an LRDIMM comprising a plurality of DRAM chips.

Example 31 is a method for training one or more signal timing relations of a control interface between a registering clock driver and one or more data buffers of a memory module comprising a plurality of memory chips, the control interface comprising a clock signal and at least one further control signal. The method comprises adjusting a relative timing between the at least one further control signal and the clock signal based on samples of the at least one further control signal sampled with the clock signal.

In Example 32, the method of Example 31 can further comprise communicating the sampled at least one further control signal from the one or more data buffers to the host memory controller via a data bus between the one or more data buffers and a host memory controller.

In Example 33, adjusting the relative timing of Example 31 or 32 can comprise adjusting, in the registering clock driver, a delay of the clock signal or the at least one further control signal received from a host memory controller.

In Example 34, adjusting the relative timing of any one of Examples 31 to 33 can comprise varying an adjustable relative delay between the at least one further control signal and the clock signal within a first relative delay and a second relative delay, for each relative delay, transmitting a predetermined control signal having the relative delay from the registering clock driver to the one or more data buffers, and, for each relative delay, sampling the predetermined control signal at the one or more data buffers using the clock signal.

In Example 35, adjusting the relative timing of Example 34 can comprise setting the relative timing between the at least one further control signal and the clock signal based on sampled predetermined control signals corresponding to different delays.

In Example 36, adjusting the relative timing of Example 34 or 35 can comprise setting the relative timing between the at least one further control signal and the clock signal in between two relative delays corresponding to sampling time instants at falling or rising edges of a signal pulse of the predetermined control signal.

In Example 37, the method of any one of Examples 34 to 36 can comprise generating the predetermined control signal in the registering clock driver.

In Example 38, the method of any one of Examples 34 to 36 can comprise generating the predetermined control signal in a host memory controller and forwarding the predetermined control signal from the host memory controller to the registering clock driver.

In Example 39, the at least one further control signal of any one of Examples 31 to 38 comprises a chip select signal and a data buffer command bus, wherein the chip select signal is indicative of a packet on the data buffer command bus. The method can comprise adjusting a relative timing between the chip select signal and the clock signal based on samples of the chip select signal sampled with the clock signal, and adjusting a timing of the data buffer command bus relative to the adjusted chip select signal based on a combination of data buffer command bus signals associated with the adjusted chip select signal

In Example 40, the combination of Example 39 can be an XOR combination.

In Example 41, the method of any one of Examples 31 to 40 can further comprise configuring different modes of operation of the registering clock driver and/or the one or more data buffers, the different modes comprising at least one control signal delay training mode and a normal operation mode.

In Example 42, the method of Example 41 can further comprise configuring a first mode of operation of the one or more data buffers based on a first static value of the at least one further control signal, and configuring configure a second mode of operation of the one or more data buffers based on a second, different static value of the at least one further control signal.

In Example 43, the method of Example 41 or 42 can comprise configuring a first reference voltage of the one or more data buffers based on a first static data bus signal and to configure a second reference voltage based on a second, different static data bus signal.

In Example 44, the memory module of any one of Examples 31 to 43 can be an LRDIMM comprising a plurality of DRAM chips.

Example 45 is a computer program product comprising a non-transitory computer readable medium having computer readable program code embodied therein, wherein the computer readable program code, when being loaded on a computer, a processor, or a programmable hardware component, is configured to implement a method for training one or more signal timing relations of a control interface between a registering clock driver and one or more data buffers of a memory module comprising a plurality of memory chips, the control interface comprising a clock signal and at least one further control signal, the method comprising adjusting a relative timing between the at least one further control signal and the clock signal based on samples of the at least one further control signal sampled with the clock signal.

The skilled person having benefit from the present disclosure will appreciate that the various examples described herein can be implemented individually or in combination.

The aspects and features mentioned and described together with one or more of the previously detailed examples and figures, may as well be combined with one or more of the other examples in order to replace a like feature of the other example or in order to additionally introduce the feature to the other example.

Examples may further be a computer program having a program code for performing one or more of the above methods, when the computer program is executed on a computer or processor. Steps, operations or processes of various above-described methods may be performed by programmed computers or processors. Examples may also cover program storage devices such as digital data storage media, which are machine, processor or computer readable and encode machine-executable, processor-executable or computer-executable programs of instructions. The instructions perform or cause performing some or all of the acts of the above-described methods. The program storage devices may comprise or be, for instance, digital memories, magnetic storage media such as magnetic disks and magnetic tapes, hard drives, or optically readable digital data storage media. Further examples may also cover computers, processors or control units programmed to perform the acts of the above-described methods or (field) programmable logic arrays ((F)PLAs) or (field) programmable gate arrays ((F)PGAs), programmed to perform the acts of the above-described methods.

The description and drawings merely illustrate the principles of the disclosure. It will thus be appreciated that those skilled in the art will be able to devise various arrangements that, although not explicitly described or shown herein, embody the principles of the disclosure and are included within its spirit and scope. Furthermore, all examples recited herein are principally intended expressly to be only for pedagogical purposes to aid the reader in understanding the principles of the disclosure and the concepts contributed by the inventor(s) to furthering the art, and are to be construed as being without limitation to such specifically recited examples and conditions. Moreover, all statements herein reciting principles, aspects, and examples of the disclosure, as well as specific examples thereof, are intended to encompass equivalents thereof.

A functional block denoted as “means for . . . ” performing a certain function may refer to a circuit that is configured to perform a certain function. Hence, a “means for s.th.” may be implemented as a “means configured to or suited for s.th.”, such as a device or a circuit configured to or suited for the respective task.

Functions of various elements shown in the figures, including any functional blocks labeled as “means”, “means for providing a sensor signal”, “means for generating a transmit signal.”, etc., may be implemented in the form of dedicated hardware, such as “a signal provider”, “a signal processing unit”, “a processor”, “a controller”, etc. as well as hardware capable of executing software in association with appropriate software. When provided by a processor, the functions may be provided by a single dedicated processor, by a single shared processor, or by a plurality of individual processors, some of which or all of which may be shared. However, the term “processor” or “controller” is by far not limited to hardware exclusively capable of executing software, but may include digital signal processor (DSP) hardware, network processor, application specific integrated circuit (ASIC), field programmable gate array (FPGA), read only memory (ROM) for storing software, random access memory (RAM), and nonvolatile storage. Other hardware, conventional and/or custom, may also be included.

A block diagram may, for instance, illustrate a high-level circuit diagram implementing the principles of the disclosure. Similarly, a flow chart, a flow diagram, a state transition diagram, a pseudo code, and the like may represent various processes, operations or steps, which may, for instance, be substantially represented in computer readable medium and so executed by a computer or processor, whether or not such computer or processor is explicitly shown. Methods disclosed in the specification or in the claims may be implemented by a device having means for performing each of the respective acts of these methods.

It is to be understood that the disclosure of multiple acts, processes, operations, steps or functions disclosed in the specification or claims may not be construed as to be within the specific order, unless explicitly or implicitly stated otherwise, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts, -functions, -processes, -operations or -steps, respectively. Such sub acts may be included and part of the disclosure of this single act unless explicitly excluded.

Furthermore, the following claims are hereby incorporated into the detailed description, where each claim may stand on its own as a separate example. While each claim may stand on its own as a separate example, it is to be noted that—although a dependent claim may refer in the claims to a specific combination with one or more other claims—other examples may also include a combination of the dependent claim with the subject matter of each other dependent or independent claim. Such combinations are explicitly proposed herein unless it is stated that a specific combination is not intended. Furthermore, it is intended to include also features of a claim to any other independent claim even if this claim is not directly made dependent to the independent claim.

What is claimed is:

1. An apparatus for training one or more signal timing relations of a memory interface, the apparatus comprising:
control circuitry configured to adjust a relative timing between at least one control signal and a clock signal of a control interface between a registering clock driver and one or more data buffers of a memory module based on samples of the at least one control signal sampled based on the clock signal.

2. The apparatus of claim 1, further comprising a data bus between the one or more data buffers and a host memory controller for communicating the sampled at least one control signal from the one or more data buffers to the host memory controller.

3. The apparatus of claim 1, wherein the control circuitry is configured to adjust, in the registering clock driver, a delay of the clock signal or the at least one control signal received from a host memory controller.

4. The apparatus of claim 1, wherein the control circuitry is configured to
vary an adjustable relative delay between the at least one control signal and the clock signal within a first relative delay and a second relative delay,
for each relative delay, transmit a predetermined control signal having the relative delay from the registering clock driver to the one or more data buffers, and
for each relative delay, sample the predetermined control signal at the one or more data buffers using the clock signal.

5. The apparatus of claim 4, wherein the control circuitry is configured to set the relative timing between the at least one control signal and the clock signal based on sampled predetermined control signals corresponding to different relative delays.

6. The apparatus of claim 4, wherein the control circuitry is configured to set the relative timing between the at least one control signal and the clock signal in between two relative delays corresponding to sampling time instants at falling or rising edges of a signal pulse of the predetermined control signal.

7. The apparatus of claim 4, wherein the control circuitry comprises a pattern generator in the registering clock driver configured to generate the predetermined control signal.

8. The apparatus of claim 4, wherein the control circuitry comprises
a pattern generator in a host memory controller configured to generate the predetermined control signal, and
an interface between the host memory controller and the registering clock driver to transmit the predetermined control signal from the host memory controller to the registering clock driver.

9. The apparatus of claim 1, wherein the at least one control signal comprises a chip select signal and a data buffer command bus, wherein the chip select signal is indicative of a packet on the data buffer command bus,
wherein the control circuitry is configured to
adjust a relative timing between the chip select signal and the clock signal based on samples of the chip select signal sampled with the clock signal, and
to adjust a timing of the data buffer command bus relative to the adjusted chip select signal based on a combination of data buffer command bus signals asserted using the adjusted chip select signal.

10. The apparatus of claim 9, wherein the control circuitry is configured to
vary an adjustable relative delay between the chip select signal and the clock signal within a first relative delay and a second relative delay,
for each relative delay, transmit a predetermined chip select signal using the current relative delay from the registering clock driver to the one or more data buffers, and
for each relative delay, sample the predetermined chip select signal at the one or more data buffers at rising or falling edges of the clock signal.

11. The apparatus of claim 10, wherein the control circuitry is configured to set the relative timing between the chip select signal and the clock signal in between two relative delays corresponding to sampling time instants at falling or rising edges of a signal pulse of the predetermined chip select signal.

12. The apparatus of claim 9, wherein the control circuitry is configured to
vary an adjustable relative delay between the data buffer command bus and the adjusted chip select signal within a first relative delay and a second relative delay,
for each relative delay, transmit from the registering clock driver to the one or more data buffers, predetermined data buffer command bus signals using the current relative delay, and
for each relative delay, combine the predetermined data buffer command bus signals corresponding to an associated chip select signal.

13. The apparatus of claim 12, wherein the control circuitry is configured to combine the predetermined data buffer command bus signals by an XOR operation.

14. The apparatus of claim 12, wherein the control circuitry is configured to set the relative timing between the data buffer command bus and the clock signal in between two relative delays corresponding to false results of the combination of the predetermined data buffer command bus signals.

15. The apparatus of claim 1, wherein the control circuitry is configured to
configure different modes of operation of the registering clock driver and/or the one or more data buffers, the different modes comprising
at least one control signal delay training mode and a normal operation mode.

16. The apparatus of claim 15, wherein the control circuitry is configured to
configure a first mode of operation of the one or more data buffers based on a first static value of the at least one control signal and
to configure a second mode of operation of the one or more data buffers based on a second, different static value of the at least one control signal.

17. The apparatus of claim 15, wherein the control circuitry is configured to configure a first reference voltage of the one or more data buffers based on a first static data bus signal and to configure a second reference voltage based on a second, different static data bus signal.

18. The apparatus of claim 1, wherein the memory module is an LRDIMM comprising a plurality of DRAM chips.

19. A memory system, comprising:
a memory controller;
a memory module comprising
a plurality of memory chips,
a registering clock driver, and
one or more data buffers associated with the plurality of memory chips, and
an internal interface between the registering clock driver and the one or more data buffers the internal interface comprising a clock signal and at least one control signal, an external control bus between the memory controller and the registering clock driver;
an external data bus between the memory controller and the one or more data buffers;
wherein the memory controller is configured to
adjust, via the external control bus, a relative timing of the internal interface between the at least one control signal and the clock signal based on samples of the at least one control signal sampled at the one or more data buffers based on the clock signal and communicated to the memory controller via the external data bus.

20. The memory system of claim 19, wherein the memory controller is configured to set a relative timing between the control signal and the clock signal,
to send a predetermined control signal with the set relative timing from the registering clock driver to the one or more data buffers, and
to sample the predetermined control signal at the one or more data buffers using the clock signal.

21. A method for training one or more signal timing relations of a control interface between a registering clock driver and one or more data buffers of a memory module comprising a plurality of memory chips, the control interface comprising a clock signal and at least one further control signal, the method comprising:
adjusting a relative timing between the at least one further control signal and the clock signal based on samples of the at least one further control signal sampled with the clock signal.

22. The method of claim 21, further comprising
communicating the sampled at least one further control signal from the one or more data buffers to the host memory controller via a data bus between the one or more data buffers and a host memory controller.

23. The method of claim 21, wherein adjusting the relative timing comprises adjusting, in the registering clock driver, a delay of the clock signal or the at least one further control signal received from a host memory controller.

24. The method of claim 21, wherein adjusting the relative timing comprises
varying an adjustable relative delay between the at least one further control signal and the clock signal within a first relative delay and a second relative delay,
for each relative delay, transmitting a predetermined control signal having the relative delay from the registering clock driver to the one or more data buffers, and
for each relative delay, sampling the predetermined control signal at the one or more data buffers using the clock signal.

25. The method of claim 24, wherein adjusting the relative timing comprises
setting the relative timing between the at least one further control signal and the clock signal based on sampled predetermined control signals corresponding to different delays.
